(19) United States
(12) Patent Application Publication
(10) Pub. No.: US 2007/0290341 A1
(43) Pub. Date: Dec. 20, 2007

(54) SEMICONDUCTOR PACKAGE AND METHOD OF MOUNTING THE SAME

(75) Inventor: Chang-Young PARK, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/762,604

(22) Filed: Jun. 13, 2007

(30) Foreign Application Priority Data
Jun. 19, 2006 (KR) 2006-0054924

(51) Int. Cl. H01L 23/48; H01L 21/44

(52) U.S. Cl. 257/737; 438/613; 257/E23.021; 257/784

(57) ABSTRACT

A semiconductor package having a good joint to an external board, providing easy measurement control of the electrical characteristics of a semiconductor chip, and ensuring a sufficient number of input and output terminals, and a method of mounting the same are provided. The semiconductor package comprises a plurality of connection terminals aligned individually, and a plurality of conductive wires spaced from the connection terminals. The connection terminals and the wires are bonded to one side of a body, and an interconnection connecting at least one pair of the connection terminal and the wire is formed in the body.

### CROSS-REFERENCE TO RELATED PATENT APPLICATION

This application claims priority from Korean Patent Application No. 10-2006-0054924, filed on Jun. 19, 2006, in the Korean Intellectual Property Office, the disclosure of which is incorporated herein in its entirety by reference.

### BACKGROUND

1. Technical Field

The present invention relates to a semiconductor package and a method of mounting the same, and more particularly, to a semiconductor package using interconnections electrically connecting a solder connection terminal such as a ball and a conductive wire, and a method of mounting the same.

2. Description of the Related Art

Normally, a sealed semiconductor chip is electrically connected to an external board using various methods. For example, the sealed chip can be attached to the external board using a solder joint, a wire, or a lead frame. However, these methods have many problems.

The solder joint method may use relatively wide areas for interconnections, but when the sealed chip is attached to the external board, solder joint reliability is deteriorated. For example, the solder joint may be detached or broken due to physical impact or heat. When using the wire method, the wire is reliably attached to the external board, but it is difficult to measure the electrical characteristics of the chip to which the wire is attached. The lead frame has drawbacks in that the number of input and output terminals is limited, and the electrical characteristics are relatively poor. Therefore, it is necessary to develop a semiconductor package which enables the electrical characteristics of a semiconductor chip to be checked easily, ensures a sufficient number of input and output terminals, and provides a good connection with an external board.

### SUMMARY

Some embodiments of the present invention provide a semiconductor package having a good joint between a sealed semiconductor chip and an external board, providing easy measurement of the electrical characteristics of the semiconductor chip, and ensuring a sufficient number of input and output terminals. The present invention also provides a method of mounting the package.

According to an aspect of the present invention, there is provided a semiconductor package comprising a plurality of connection terminals and a plurality of conductive wires spaced apart from the connection terminals. The connection terminals and the wires are bonded to one side of a body, and an interconnection connecting at least one pair of the connection terminals and the wires is formed in the body.

### BRIEF DESCRIPTION OF THE DRAWINGS

The above and other features and advantages of the present invention will become more apparent by describing in detail exemplary embodiments thereof with reference to the attached drawings in which:

FIG. 1A is a sectional view illustrating a semiconductor package according to an embodiment of the present invention;

FIG. 1B is a plan view illustrating a body having a conductive pad, for example, a substrate, according to an embodiment of the present invention;

FIG. 2 is a sectional view illustrating a modified example of an interconnection of the semiconductor package in the embodiment of the present invention shown in FIG. 1A;

FIG. 3 is a perspective view illustrating a method for mounting the semiconductor package in the embodiment of the present invention shown in FIG. 1A on an external circuit board; and

FIG. 4 is a perspective view illustrating a semiconductor package according to another embodiment mounted on an external circuit board.

### DETAILED DESCRIPTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like reference numbers refer to like elements throughout the specification.

Embodiments of the present invention provide a semiconductor package including an interconnection connecting a solder connection terminal and a conductive wire, and a method of mounting the semiconductor package. For clarity of explanation, the embodiments of the present invention are divided in accordance with sealed shapes of a semiconductor chip.

### First Embodiment

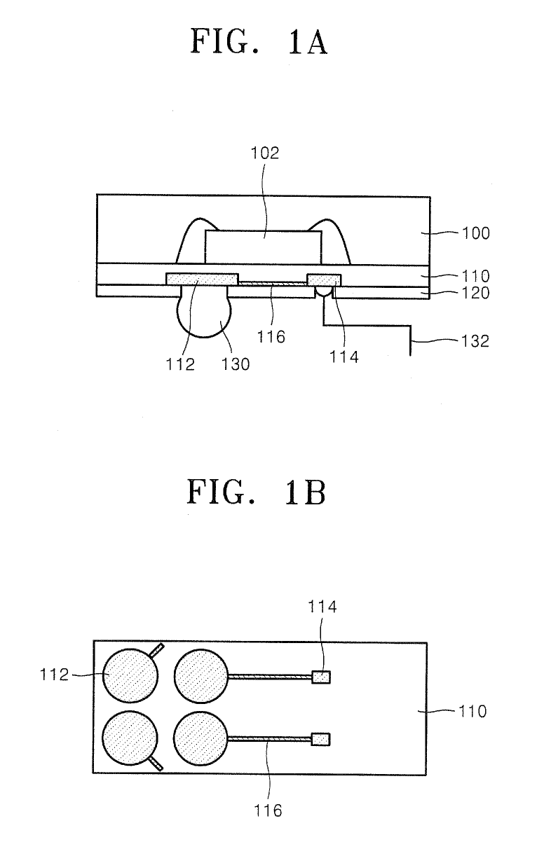

FIG. 1A is a cross-sectional view illustrating a semiconductor package according to an embodiment of the present invention, and FIG. 1B is a plan view illustrating a body having conductive pads disposed thereon. Here, the plan view illustrates a substrate.

Referring to FIGS. 1A and 1B, a semiconductor chip 102 is disposed on one side of the body 110, for example, a substrate, and a plurality of connection terminals, e.g., solder connection terminals 130 are disposed on the other side (hereinafter, rear side) of the substrate 110. One side of the substrate 110 including the semiconductor chip 102 may be referred to as a first surface and the other side may be referred to as a second surface. The plurality of solder connection terminals 130 are disposed individually. In other words, the solder connection terminals are not connected together. A plurality of conductive wires 132 externally protrude through a resist layer such as a photosensitive resist layer 120. The connection terminal 130 and the wire 132 protrude in substantially the same direction so as to be mounted on an external board (150 of FIG. 3). The semiconductor chip 102 is encapsulated or sealed by a molding material 100 such as an epoxy molding compound.

The connection terminal 130 and the wire 132 are electrically connected through an interconnection 116 so as to form at least one pair. That is, the substrate 110 includes a first bonding pad 112 electrically and mechanically bonded to the connection terminal 130, a second bonding pad 114 bonded to the wire 132, and an interconnection 116 electrically connecting the first and second bonding pads 112 and 114. FIG. 1A illustrates just one pair of the first bonding pad 112 and the second bonding pad 114, but in an actual package, a plurality of the first bonding pads 112 and a plurality of the second bonding pads 114 may be formed on the rear side of the substrate 110. Here, the first and second bonding pads 112 and 114 bonded with the connection terminal 130 and the wire 132, respectively, and the interconnection 116, which contacts the photosensitive resist layer 120, may be disposed at substantially the same level as the surface of the rear side of the substrate 110. In other words, the first and second bonding pads 112 and 114 and the interconnection 116 may be disposed at substantially the same level as the second surface of the substrate 110.

The interconnections 116 may be formed to make pairs of the connection terminals 130 and the wires 132, respectively. For example, when hundred (100) connection terminals 130 are disposed in the substrate 110, the interconnections 116 may be formed to make pairs of all of the hundred (100) connection terminals 130 with hundred (100) wires 132, respectively.

If necessary, the interconnections 116 may be formed to make pairs of some of the connection terminals 130 and their corresponding wires 132, respectively. In other words, the interconnections 116 may be used to connect a subset of the connection terminals 130 to a subset of the wires 132. The reason that some of the connection terminals 130 are made to form pairs is to determine in advance the connection terminals 130 that are weakly bonded, to control the number of desired input and output terminals, or for various other purposes. For instance, connection terminals 130 that are not susceptible to failure from physical impact or heat, due to their position on the substrate or other factors, may not form pairs with wires 132.

The interconnection 116 may be formed by etching the substrate 110 between the first and second bonding pads 112 and 114 to a predetermined depth and then filling the etched portion with a conductive material.

The connection terminal 130 may be formed by typical fabrication methods, for example, by a reflow process, so that the connection terminal 130 can be connected to an external circuit board. The connection terminal 130 may be a ball-shaped solder ball, or a bump-shaped solder bump. Further, the wire 132 may be formed using a normal wire bonding method or using a tape having the wire 132 bonded thereon. The surface of the wire 132 may be coated with an insulating layer, thereby improving the strength of the wire 132, and preventing electrical shorts between adjacent wires.

Both of the connection terminal 130 and the wire 132 according to the embodiment of the present invention shown in FIGS. 1A and 1B may be used as input and output terminals. Therefore, the package of the present invention ensures sufficient input and output terminals.

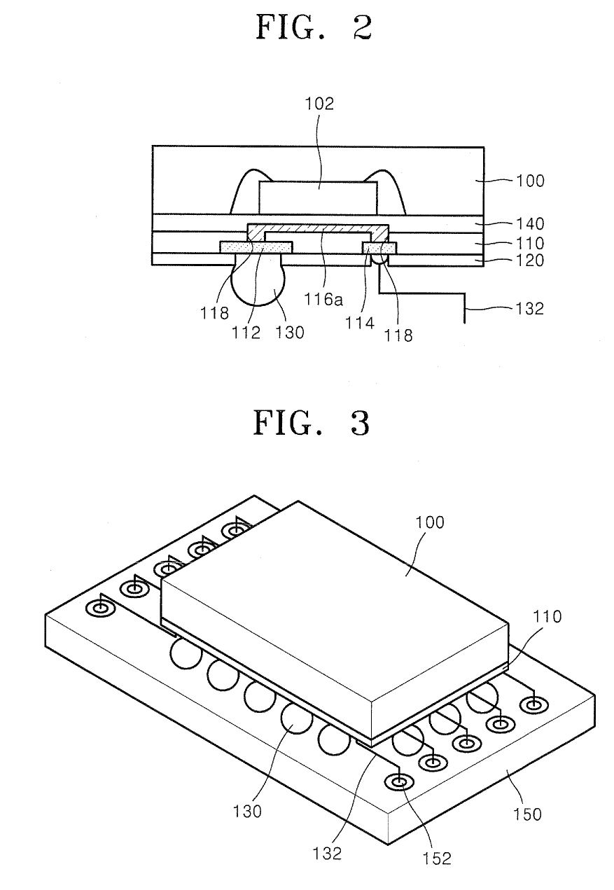

FIG. 2 is a sectional view illustrating a modified example of an interconnection of the semiconductor package in the embodiment of the present invention shown in FIG. 1A. FIG. 2 is identical to FIG. 1A except for the package and the interconnection 116a. That is, like reference numbers of FIG. 1A refer to like elements.

Referring to FIG. 2, the interconnection 116a is communicated with via holes 118, which are formed perpendicular to a rear side of a substrate 110. In particular, before first and second bonding pads 112 and 114 are formed, the via holes 118 are formed to penetrate the substrate 110 disposed below the bonding pads 112 and 114. Then, by filling the via holes 118 with a conductive material for interconnection, and connecting the conductive material filled in the via holes, the interconnection 116a is formed. At this time, the interconnection 116a may be formed using a separate insulating layer 140, or may be formed in the substrate 110.

FIG. 3 is a perspective view illustrating a method for mounting the semiconductor package in the embodiment of the present invention shown in FIG. 1A on an external circuit board. If necessary, FIGS. 1A and 1B will be referred to.

Referring to FIG. 3, a plurality of first and second bonding pads 112 and 114 are formed in a body 110 including a semiconductor chip 102. Then, an interconnection 116, which electrically connects at least one pair of the first and second bonding pads 112 and 114, is formed. At least one of solder connection terminals 130 may be bonded to a corresponding one of the first bonding pads 112. The solder connection terminals 130 are also formed on other first bonding pads 112 that do not form a pair with the second bonding pads 114. Then, a conductive wire 132 may be bonded to the second bonding pad 114, which forms a pair with the first bonding pad 112. Then, the solder connection terminal 130 and the conductive wire 132 are attached to an external circuit board 150 in which electrical connection pads 152 are formed corresponding to the first and second bonding pads 112 and 114. The interconnections 116 may be formed to enable all the connection terminals 130 and the wires 132 to make pairs. For example, when hundred (100) connection terminals 130 are disposed in the substrate 110, the interconnections 116 may be formed to make pairs of all the hundred (100) connection terminals 130 with 100 wires 132. If necessary, the interconnections 116 may be formed to make pairs of some of the connection terminals 130 and the wires 132, respectively. In other words, the interconnections 116 may be used to connect a subset of the connection terminals 130 to a subset of the wires 132. The reason that some of the connection terminals 130 are made to form pairs is to determine in advance the connection terminals 130 that are weakly bonded, to control the number of desired input and output terminals, or for various other purposes.

At this time, the electrical characteristics of the semiconductor chip 100 can be measured after attaching the solder connection terminal 130 and the conductive wire 132 to the external circuit board 150. If necessary, the characteristics may be measured after attaching the solder connection terminal 130, that is, before attaching the conductive wire 132. The solder connection terminal 130, which is easy to measure, is electrically tested, and the solder connection terminal 130 may be attached to the external circuit board 150 along with the wire 132, which is reliably attached to the external circuit board 150. The solder connection terminal 130 and the conductive wire 132 may be attached to the external circuit board 150 using a reflow process.

The method of mounting the semiconductor package of FIG. 1A uses the solder connection terminal 130 and uses relatively wide areas as interconnections. Therefore, the present invention provides an advantage over conventional methods in that the electrical characteristics of the semiconductor chip 100 can be easily measured. Further, since the wire 132 having an excellent joint reliability with the external circuit board 150 is used, even if the connection terminal 130 is detached due to a physical impact or heat, the connection is maintained by the wire 132. Furthermore, since all the connection terminals 130 and the wires 132 may be used as input and output terminals, a sufficient number of the input and output terminals can be ensured.

### Second Embodiment

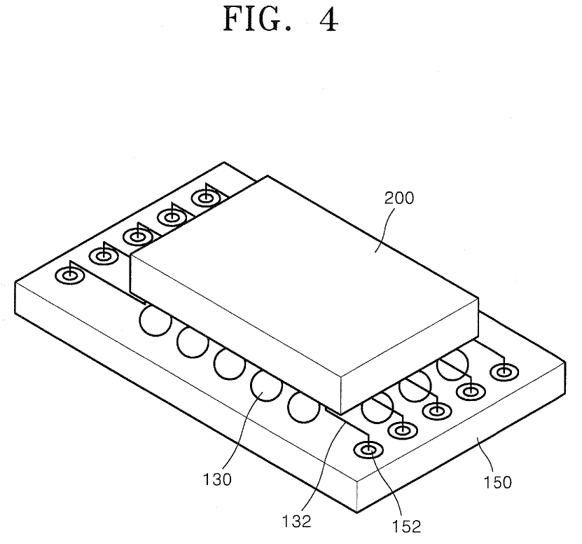

FIG. 4 is a perspective view illustrating a semiconductor package according to another embodiment mounted on an external circuit board. The embodiment of the present invention shown in FIG. 4 is different from the embodiment of FIG. 1A in that the connection terminal, the wire, and the interconnection like FIG. 1A are formed in the semiconductor chip without use of the substrate.

Referring to FIG. 4, a connection terminal 130, a wire 132, and an interconnection 116 (FIG. 1A), which have been explained with reference to FIG. 1A, are formed in an active area of a flip chip 200. The active area is the portion where the flip chip 200 contacts an external circuit board 150. In the flip chip 200, the connection terminal 130 may be fabricated as a bump shape, using an electroplating method.

According to the embodiment of the present invention shown in FIG. 4, it is proposed that the connection terminal, the wire, and the interconnection, which are characteristic components of the present invention, can be applied to various shapes of packages.

As described above, in the semiconductor package and the method of mounting the same according to embodiments of the present invention, the electrical characteristics can be easily measured because the relatively wide areas can be used as interconnections by using the solder connection terminals. Further, although the connection terminal may be detached due to impact or heat, since a joint reliability of the wire to the external circuit board is excellent, the connection can be maintained by the wire. Furthermore, since all of the connection terminals and wires can be used as input and output terminals, a sufficient number of input and output terminals can be ensured.

According to an aspect of the present invention, there is provided a semiconductor package comprising a plurality of connection terminals and a plurality of conductive wires spaced apart from the connection terminals. The connection terminals and the conductive wires are bonded to one side of a body, and an interconnection connecting at least one pair of the connections terminal and the conductive wires is formed in the body.

In the embodiment of the present invention, the interconnection may be formed on one side of the body so as to be at the same level as the surface of the side, and the interconnection may be formed by connecting via holes formed perpendicular to one side of the body. Further, the interconnections may electrically connect a subset of the connection terminals and the conductive wires, or the interconnections may electrically connect all of the connection terminals and the conductive wires.

According to another aspect of the present invention, there is provided a method of mounting a semiconductor package comprising forming a plurality of first and second bonding pads on a body comprising a semiconductor chip. Then, an interconnection electrically connecting at least one pair of the first and second bonding pads may be formed. A solder connection terminal is bonded to the first bonding pad. A conductive wire is bonded to the second bonding pad corresponding to the first bonding pad to form one pair. The solder connection terminal and the conductive wire are attached to an external circuit board having electrical connection pads corresponding to the first and second bonding pads.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a plurality of connection terminals;
a plurality of conductive wires spaced apart from the connection terminals;
a body having the connection terminals and the wires bonded on one side of the body; and
one or more interconnections disposed in the body, and connecting at least one of the connection terminals to a corresponding one of the conductive wires.

2. The semiconductor package of claim 1, wherein the body further comprises bonding pads bonded to the connection terminals and the conductive wires respectively.

3. The semiconductor package of claim 1, wherein at least one of the connection terminals is a ball-shaped solder ball.

4. The semiconductor package of claim 1, wherein at least one of the connection terminals is a bump-shaped solder bump.

5. The semiconductor package of claim 1, wherein the conductive wires are covered by an insulating layer.

6. The semiconductor package of claim 1, wherein the body is a substrate to which a semiconductor chip is attached.

7. The semiconductor package of claim 1, wherein the body is a semiconductor chip.

8. The semiconductor package of claim 1, wherein the one or more interconnections are formed on one side of the body so as to be at substantially the same level as the surface of the side of the body.

9. The semiconductor package of claim 1, wherein the one or more interconnections are formed by connecting vias disposed perpendicular to one side of the body.

10. The semiconductor package of claim 1, wherein the one or more interconnections electrically connect a subset of the connection terminals and a subset of the conductive wires.

11. The semiconductor package of claim 1, wherein the one or more interconnections electrically connect all of the connection terminals and all of the conductive wires.

12. A method of mounting a semiconductor package comprising:
forming a plurality of first and second bonding pads on a body including a semiconductor chip;
forming one or more interconnections electrically connecting at least one of the first bonding pads to corresponding one of the second bonding pads;
bonding a connection terminal to the first bonding pad;
bonding a conductive wire to the second bonding pad that is connected to the first bonding pad having the connection terminal to form one pair; and
attaching the connection terminal and the conductive wire to an external circuit board having electrical connection pads corresponding to the first and second bonding pads.

13. The method of claim 12, wherein the forming of the one or more interconnections comprises:
etching one side of the body between the first and second bonding pads; and
filling the etched portion with a conductive material for interconnection.

14. The method of claim 12, wherein, before forming the bonding pads, the forming of the interconnection comprises:
forming via holes penetrating the body where the first and second bonding pads are to be formed;
filling the via holes with a conductive material for interconnection; and
connecting the conductive material filled in the via holes.

15. The method of claim 14, further comprising forming an insulating layer on the body, prior to forming the via holes.

16. The method of claim 12, after bonding the conductive wire, the method further comprising measuring the electrical characteristics of the semiconductor chip.

17. The method of claim 12, before bonding the conductive wire, the method further comprising measuring the electrical characteristics of the semiconductor chip.

18. The method of claim 12, wherein attaching the connection terminal and the conductive wire to the external circuit board comprises a reflow process.

19. A semiconductor package comprising:
a substrate;
a semiconductor chip disposed on a first surface of the substrate;
a resist layer disposed on a second surface of the substrate;
a plurality of connection terminals disposed on the second surface and penetrating the resist layer;
a plurality of conductive wires disposed on the second surface, the conductive wires penetrating the resist layer and spaced apart from the connection terminals; and
one or more interconnections disposed in the substrate, and connecting at least one of the connection terminals to a corresponding one of the conductive wires.

20. The semiconductor package of claim 19, further comprising a plurality of bonding pads disposed in the substrate beneath the connection terminals and the conductive wires respectively, and wherein the interconnection connects a first bonding pad under the at least one connection terminal to a second bonding pad under the at least one conductive wire.
